(19) United States
(12) Patent Application Publication
(10) Pub. No.: US 2025/0279362 A1
(43) Pub. Date: Sep. 4, 2025

(54) CHIP PACKAGE STRUCTURES AND FABRICATION METHODS THEREOF, MEMORY SYSTEMS AND ELECTRONIC APPARATUSES

(71) Applicant: YANGTZE MEMORY TECHNOLOGIES CO., LTD., Wuhan (CN)

(72) Inventor: Peng SUN, Wuhan (CN)

(21) Appl. No.: 19/012,120

(22) Filed: Jan. 7, 2025

(30) Foreign Application Priority Data
Feb. 29, 2024 (CN) 202410238454.6

(51) Int. Cl. H01L 23/528; H01L 21/306; H01L 21/3065; H01L 21/768; H01L 23/00; H01L 25/16; H10B 80/00; H10D 80/30

(52) U.S. Cl. CPC H01L 23/5283; H01L 21/30604; H01L 21/3065; H01L 21/76877; H01L 21/76898; H01L 23/528; H01L 24/32; H01L 25/16; H10B 80/00; H10D 80/30; H01L 24/16; H01L 24/73; H01L 2224/16146; H01L 2224/32145; H01L 2224/73203; H01L 2225/06513; H01L 2225/06544; H01L 2924/1431

(57) ABSTRACT

The present disclosure provides a chip package structure and a fabrication method thereof, a memory system, and an electronic apparatus, and relates to the field of chip package technology. The chip package structure includes a stack structure and at least one first conductive pillar. The stack structure includes a plurality of semiconductor structures that are stacked. The stack structure includes a first surface and a second surface that are opposite in a stacking direction. The first conductive pillar extends along the stacking direction from the first surface of the stack structure, penetrates through at least one of the semiconductor structures, and is connected to one of the semiconductor structures. The above-mentioned chip package structure may be applied in a memory system to realize read and write operations of data.

### CROSS-REFERENCE TO RELATED APPLICATIONS

The present application claims the benefit of priority to Chinese Application No. 202410238454.6, filed on Feb. 29, 2024, which is hereby incorporated by reference in its entirety.

### TECHNICAL FIELD

The present disclosure relates to the field of chip package technology, and, in particular, to chip package structures, fabrication methods thereof, memory systems and electronic apparatuses.

### BACKGROUND

Some semiconductor chips (for example, flash memories) have been widely used for data storage. Users of these semiconductor chips expect that the storage capacity of data storage may keep increasing, and manufacturers seek to provide large storage capacity at low costs while maintaining a standard package size, to ensure compatibility with existing electronic devices.

### SUMMARY

According to one aspect of the present disclosure, a chip package structure is provided, the chip package structure may include a stack structure and at least one first conductive pillar.

The stack structure may include a plurality of semiconductor structures that are stacked. The stack structure may include a first surface and a second surface that are opposite in a stacking direction.

The first conductive pillar may extend along the stacking direction from the first surface of the stack structure. The first conductive pillar may penetrate through at least one of the semiconductor structures. The first conductive pillar may be connected to one of the semiconductor structures.

In some examples, the first conductive pillar is an integral structure. In some examples, a sidewall of the first conductive pillar may be an even surface or a smooth surface along the stacking direction.

In some examples, the semiconductor structures may include a functional layer and a dielectric layer that are stacked. In some examples, the semiconductor structures may include a routing layer that is located in the dielectric layer. In some examples, the routing layer is electrically connected to the functional layer.

In some examples, at least one of the semiconductor structures may further include a dielectric block. In some examples, the dielectric block at least penetrates along the stacking direction through the routing layer of the semiconductor structure in which the dielectric block is located.

In some examples, the first conductive pillar penetrates through the dielectric block. In some examples, the first conductive pillar connected to the routing layer of one of the semiconductor structures located on a side of the dielectric block close to the second surface.

In some examples, the semiconductor structures except the one closest to the second surface each include the dielectric block.

In some examples, in the stacking direction, a plurality of dielectric blocks located in different semiconductor structures overlap in the same region. In some examples, the at least one first conductive pillar penetrates through the plurality of dielectric blocks that overlap in the same region and is connected to the routing layer of one of the semiconductor structures.

In some examples, a plurality of first conductive pillars are disposed as penetrating through the dielectric block of at least one of the semiconductor structures.

In some examples, a number of the first conductive pillars disposed as penetrating through the dielectric blocks of the plurality of semiconductor structures decreases sequentially along a direction from the first surface to the second surface.

In some examples, areas of the plurality of dielectric blocks located in the different semiconductor structures are the same.

In some examples, along the stacking direction, the plurality of dielectric blocks are staggered along a same direction parallel to the second surface.

In some examples, areas of the plurality of dielectric blocks located in the different semiconductor structures decrease sequentially along a direction from the first surface to the second surface.

In some examples, the chip package structure may further include at least one bonding layer, wherein two adjacent ones of the semiconductor structures are connected by the bonding layer.

In some examples, the first conductive pillar penetrates through the at least one bonding layer.

In some examples, the chip package structure may further include an insulation layer surrounding the first conductive pillar and located at least between the first conductive pillar and the bonding layer that the first conductive pillar penetrates through.

In some examples, the insulation layer is further located between the first conductive pillar and the functional layer of the semiconductor structure that the first conductive pillar penetrates through.

In some examples, the chip package structure includes a plurality of first conductive pillars, and the semiconductor structures except the one closest to the first surface each are connected to at least one of the first conductive pillars.

In some examples, the chip package structure further includes at least one second conductive pillar. In some examples, one end of the second conductive pillar is connected to the semiconductor structure closest to the first surface, and the other end of the second conductive pillar extends to the first surface.

In some examples, the chip package structure further includes a transfer layer disposed on a side of the first surface of the stack structure.

In some examples, the first conductive pillar and the second conductive pillar each are connected to the transfer layer.

According to another aspect of the present disclosure, a fabrication method of a chip package structure is provided. The method may include forming a plurality of semiconductor structures. The semiconductor structures may include a functional layer and a dielectric layer that are stacked. A routing layer may be located in the dielectric layer. The routing layer may be electrically connected to the functional layer. The method may include forming a dielectric block in at least one of the semiconductor structures. The dielectric block may at least penetrates through the routing layer of the semiconductor structure. The method may include forming a stack structure by stacking the plurality of semiconductor structures. The stack structure may include a first surface and a second surface that are opposite in a stacking direction. The method may include forming at least one via. The via may extend along the stacking direction from the first surface. The via may penetrate through the dielectric block and the functional layer of at least one of the semiconductor structures. The via may stop at the routing layer of one of the semiconductor structures. The method may include forming a first conductive pillar within the via. An end of the first conductive pillar may be connected to the routing layer of one of the semiconductor structures.

In some examples, the forming at least one via may include etching the dielectric block and the functional layer of at least one of the semiconductor structures through a first etching process.

In some examples, the first etching process may include a plasma etching process.

In some examples, based on that the dielectric block penetrates along the stacking direction through the routing layer of the semiconductor structure in which the dielectric block is located, between the forming the dielectric block in at least one of the semiconductor structures and the forming the stack structure by stacking the plurality of semiconductor structures, the fabrication method may further include forming at least one sacrificial layer pattern in the dielectric block and the dielectric layer. The sacrificial layer pattern penetrates through the dielectric block and the dielectric layer. The sacrificial layer pattern may include the same material as a portion of material of the functional layer.

In some examples, based on that the dielectric block penetrates along the stacking direction through the routing layer and the dielectric layer of the semiconductor structure in which the dielectric block is located, between the forming the dielectric block in at least one of the semiconductor structures and the forming the stack structure by stacking the plurality of semiconductor structures, the fabrication method may further include forming at least one sacrificial layer pattern in the dielectric block. The sacrificial layer pattern penetrates through the dielectric block. The sacrificial layer pattern may include the same material as a portion of material of the functional layer.

In some examples, the forming at least one via may include etching the sacrificial layer pattern and the functional layer of at least one of the semiconductor structures through a second etching process.

In some examples, the second etching process may include a wet etching process.

In some examples, the forming at least one via may include forming one first via. The first via may extend along the stacking direction from the first surface. The first via may penetrate through the dielectric block and the functional layer of at least one of the semiconductor structures. The first via may stop at the routing layer of one of the semiconductor structures. In some examples, forming one second via in a process of forming the first via. The second via may extend along the stacking direction from the first surface. The second via may penetrate through the dielectric blocks and the functional layers of at least two of the semiconductor structures. The second via may stop at the routing layer of another one of the semiconductor structures.

In some examples, the forming the first conductive pillar within the via may include forming the first conductive pillar within the first via. In some examples, forming the first conductive pillar within the second via in a process of forming the first conductive pillar within the first via.

According to another aspect of the present disclosure, a memory system is provided. The memory system may include a chip package structure. The chip package structure may include a stack structure and at least one first conductive pillar. The stack structure may include a plurality of semiconductor structures that are stacked. The stack structure may include a first surface and a second surface that are opposite in a stacking direction. The first conductive pillar may extend along the stacking direction from the first surface of the stack structure. The first conductive pillar may penetrate through at least one of the semiconductor structures. The first conductive pillar may be connected to one of the semiconductor structures. The memory system may further include a controller connected to the chip package structure.

According to a further aspect of the present disclosure, an electronic apparatus is provided. The electronic apparatus may include a memory system. The memory system may include a chip package structure. The chip package structure may include a stack structure and at least one first conductive pillar. The stack structure may include a plurality of semiconductor structures that are stacked. The stack structure may include a first surface and a second surface that are opposite in a stacking direction. The first conductive pillar may extend along the stacking direction from the first surface of the stack structure. The first conductive pillar may penetrate through at least one of the semiconductor structures. The first conductive pillar may be connected to one of the semiconductor structures. The memory system may further include a controller connected to the chip package structure. The electronic apparatus may further include a processor coupled to the memory system.

### BRIEF DESCRIPTION OF THE DRAWINGS

In order to illustrate the technical solution in the present disclosure more clearly, the drawings to be used in some examples of the present disclosure will be briefly introduced below. Apparently, the drawings in the following description are only drawings of some examples of the present disclosure. Those of ordinary skills in the art may also obtain other drawings according to these drawings. In addition, the drawings in the following description may be regarded as schematic diagrams, instead of limitations to actual size of products, actual process flow of methods, actual timing of signals, etc. involved in the examples of the present disclosure.

FIG. 1 is a structural diagram of an electronic apparatus provided by some examples.

FIG. 2 is a structural diagram of a memory system provided by some examples.

FIG. 3 is a structural diagram of a chip package structure provided by some examples.

FIG. 4 is another structural diagram of a chip package structure provided by some examples.

FIG. 5 is yet another structural diagram of a chip package structure provided by some examples.

FIG. 6 is still another structural diagram of a chip package structure provided by some examples.

FIG. 7 is an enlarged view of a region AA of the chip package structure shown in FIG. 5.

FIG. 8 is a flow diagram of a fabrication method of a chip package structure provided by some examples.

FIG. 9 is a structural diagram corresponding to operation S1 in the fabrication method of the package structure shown in FIG. 8.

FIG. 10 is a structural diagram corresponding to operation S2 in the fabrication method of the package structure shown in FIG. 8.

FIG. 11 is another structural diagram corresponding to operation S2 in the fabrication method of the package structure shown in FIG. 8.

FIG. 12 is a structural diagram corresponding to operation S3 in the fabrication method of the package structure shown in FIG. 8.

FIG. 13 is a structural diagram corresponding to operation S4 in the fabrication method of the package structure shown in FIG. 8.

FIG. 14 is a structural diagram corresponding to operation S5 in the fabrication method of the package structure shown in FIG. 8.

FIG. 15 is a structural diagram corresponding to operation S21 in the fabrication method of the package structure shown in FIG. 8.

FIG. 16 is another flow diagram of a fabrication method of a chip package structure provided by some examples.

FIG. 17 is a structural diagram corresponding to operation S61 in the fabrication method of the package structure shown in FIG. 16.

FIG. 18 is yet another flow diagram of a fabrication method of a chip package structure provided by some examples.

FIG. 19 is a structural diagram corresponding to operation S62 in the fabrication method of the package structure shown in FIG. 18.

FIG. 20 is still another flow diagram of a fabrication method of a chip package structure provided by some examples.

FIG. 21 is a structural diagram corresponding to operation S4 in the fabrication method of the package structure shown in FIG. 20. and

FIG. 22 is a structural diagram corresponding to operation S5 in the fabrication method of the package structure shown in FIG. 20.

### DETAILED DESCRIPTION

The technical solutions in some examples of the present disclosure will be described below clearly and completely in conjunction with the drawings. Apparently, the examples described are only part of, but not all of, the examples of the present disclosure. All other examples obtained by those of ordinary skills in the art based on the examples provided by the present disclosure should fall in the scope of protection of the present disclosure.

In the description of the present disclosure, it is to be understood that the terms “center”, “upper”, “lower”, “front”, “rear”, “left”, “right”, “vertical”, “horizontal”, “top”, “bottom”, “inner”, “outer”, etc. indicate orientations or position relationships that are based on the orientations or position relationships as shown in the drawings, and are only intended to facilitate description of the present disclosure and to simplify the description, instead of indicating or implying that a device or an element indicated must have a specific orientation or be configured and operated in a specific orientation, and thus cannot be understood as limiting the present disclosure.

Unless specified otherwise in the context, throughout the specification and the claims, the term “include” is interpreted as an open and inclusive meaning, e.g., “including, but not limited to”. In the description of the specification, the terms “one example”, “some examples”, “an example”, or “in an example”, etc. are intended to indicate that particular features, structures, materials, or characteristics related to the example are included in at least one example of the present disclosure. The schematic representation of the above terms may not necessarily refer to the same example. Furthermore, these particular features, structures, materials, or characteristics may be included in any one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description of the examples of the present disclosure, “a plurality of” means two or more, unless stated otherwise.

In the description of some examples, the expressions “coupled” and “connected” and derivatives thereof may be used. For example, the term “connected” may be used in the description of some examples to indicate that two or more components have a direct physical contact or an electrical contact with each other. For another example, the term “coupled” may be used in the description of some examples to indicate that two or more components have direct physical contact or electrical contact. The term “coupled” may also mean that two or more components have no direct contact with each other, but still cooperate or interact with each other. The examples disclosed herein are not necessarily limited to the content herein.

The meaning of “on”, “above”, and “over” in the contents of the present disclosure should be interpreted in the broadest manner such that “on” not only means “directly on something” but also includes the meaning of “on something” with an intermediate feature or layer therebetween, and that “above” or “over” not only means “above” or “over” something but also includes the meaning of “above” or “over” something with no intermediate feature or layer therebetween (e.g., directly on something).

Example implementations are described herein with reference to a cross-sectional view and/or a planar view that are used as idealized example drawings. In the drawings, thicknesses of layers and areas of regions are exaggerated for clarity. Thus, changes in shapes relative to the drawings caused by, for example, manufacturing technology and/or tolerance, may be contemplated. Therefore, the example implementations should not be interpreted as being limited to the shapes of regions shown herein, but rather include shape deviations caused by, for example, manufacturing. For example, an etching region shown as a rectangle will typically have a curved feature. Therefore, the regions shown in the drawings are essentially schematic, and their shapes are neither intended to show actual shapes of regions of an apparatus, nor intended to limit the scope of the example implementations.

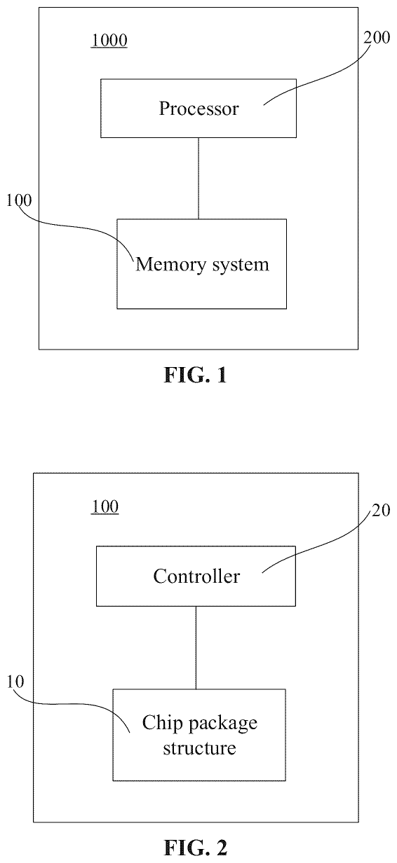

As shown in FIG. 1, some examples of the present disclosure provide an electronic apparatus 1000. The electronic apparatus 1000 includes, but is not limited to, any one of a mobile phone, a tablet computer, a laptop computer, a television, a personal digital assistant (PDA), an ultra-mobile personal computer (UMPC), a netbook, a wearable apparatus (for example, a smart watch, a smart bracelet, and smart glasses), and the like. The type of the electronic apparatus is not limited in the examples of the present application.

In some examples, with continued reference to FIG. 1, the electronic apparatus 1000 includes a memory system 100 and a processor 200. The processor 200 is coupled to the memory system 100 to interact with the memory system 100.

In an example, the processor 200 may be a central processing unit (CPU), or may be another general-purpose processor, a graphics processing unit (GPU), a system-on-chip (SoC), a digital signal processor (DSP), an application-specific integrated circuit (ASIC), a field-programmable gate array (FPGA) or another programmable logic device, a discrete gate or transistor logic device, a discrete hardware component, etc. The general-purpose processor may be a microprocessor, or the processor may be any conventional processor or the like.

The above-mentioned memory system 100 is described below in detail.

The above-mentioned memory system 100 may be integrated into a memory card. The memory card includes, for example, any one of a PC card (Personal Computer Memory Card International Association, PCMCIA), a Compact Flash (CF) card, a Smart Media (SM) card, a memory stick, a Multimedia Card (MMC), a Secure Digital Memory Card (SD) card, and a UFS.

The memory system 100 may be further integrated into various types of memory devices, for example, be included in the same package (for example, a Universal Flash Storage (UFS) package or an embedded Multi-Media Card (eMMC) package). That is, the memory system 100 can be applied to and packaged into different types of electronic products, for example, a mobile telephone (e.g. a cellphone), a desktop computer, a tablet computer, a laptop computer, a server, a vehicle apparatus, a game console, a printer, a positioning apparatus, a wearable apparatus, a smart sensor, a mobile power supply, a virtual reality (VR) apparatus, an augmented reality (AR) apparatus or any other suitable electronic apparatuses having memories therein.

In some examples, as shown in FIG. 2, FIG. 2 is a structural diagram of the memory system 100 provided by some examples of the present disclosure. The memory system 100 includes a chip package structure 10 and a controller 20. The chip package structure 10 is electrically connected to the controller 20 that may control the chip package structure 10 to store data.

In an example, the controller 20 may be integrated with the chip package structure 10, or may be disposed outside the chip package structure 10, and is electrically connected to the chip package structure 10 through leads.

In some examples, the controller 20 in the memory system 100 is configured for operating in a low duty-cycle environment, such as SD cards, CF cards, Universal Serial Bus (USB) flash drives, or other media for use in electronic apparatuses such as personal computers, digital cameras, mobile phones, etc.

In some other examples, the controller 20 is configured for operating in high duty-cycle environments like SSDs or eMMCs used as data memories for mobile apparatuses, such as smartphones, tablet computers, notebook computers, etc., and enterprise memory arrays.

In some examples, the controller 20 may be configured to manage data stored in the chip package structure 10 and communicate with an external apparatus (e.g., a host).

In some examples, the controller 20 may be further configured to control operations of the chip package structure 10, such as read, erase and program operations.

In some examples, the controller 20 may be further configured to manage various functions with respect to data stored or to be stored in the chip package structure 10, including at least one of bad-block management, garbage collection, logical-to-physical address conversion, and wear leveling.

In some examples, the controller 20 is further configured to process error correction codes with respect to the data read from or written to the chip package structure 10.

the controller 20 may also perform any other suitable functions, such as formatting the chip package structure 10. For example, the controller 20 may communicate with an external apparatus (e.g., a host) through at least one of various interface protocols.

In some examples, the interface protocols include at least one of a USB protocol, an MMC protocol, a Peripheral Component Interconnection (PCI) protocol, a PCI-Express (PCI-E) protocol, an Advanced Technology Attachment (ATA) protocol, a serial-ATA protocol, a parallel-ATA protocol, a Small Computer Small Interface (SCSI) protocol, an Enhanced Small Disk Interface (ESDI) protocol, an Integrated Drive Electronics (IDE) protocol, and a Firewire protocol.

The above-mentioned chip package structure 10 is described below in detail.

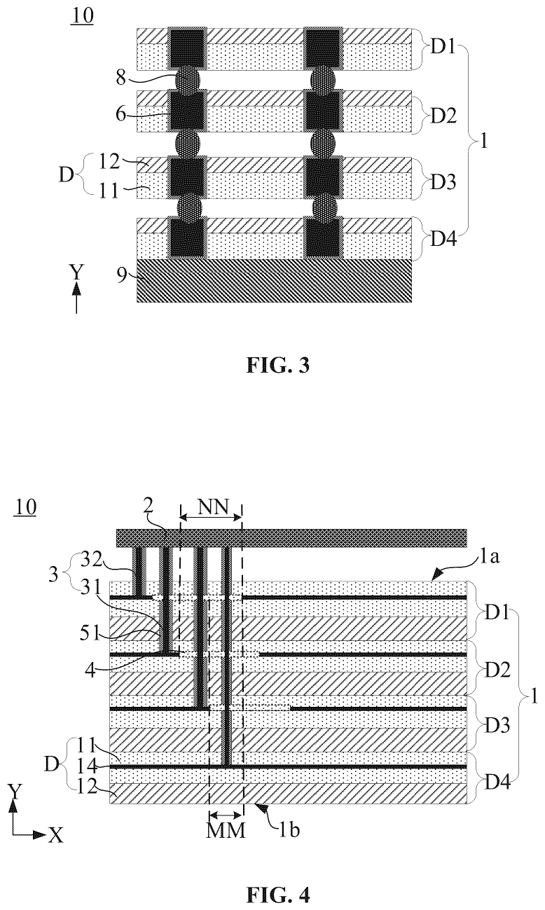

In some examples, as shown in FIG. 3, FIG. 3 is a structural diagram of the chip package structure 10 provided by some examples. The chip package structure 10 includes a stack structure 1. The stack structure 1 includes a plurality of semiconductor structures D that are stacked.

In some examples, in the example shown in FIG. 3, an example in which the stack structure 1 includes four semiconductor structures D is used for illustration. The number of the semiconductor structures D in the stack structure 1 is not limited thereto. The number of the semiconductor structures D in the stack structure 1 may be set based on the actual requirement. For example, the number of the semiconductor structures D in the stack structure 1 may be 2, 3, 5, 6, 7, 8, etc.

For ease of the description of the examples of the present disclosure, the four semiconductor structures D in the stack structure 1 are named as semiconductor structure D1, semiconductor structure D2, semiconductor structure D3, and semiconductor structure D4 respectively. The semiconductor structure D1, the semiconductor structure D2, the semiconductor structure D3, and the semiconductor structure D4 are sequentially stacked to form the stack structure 1.

In an example, the semiconductor structure D may be one of a NAND flash memory, a Dynamic Random Access Memory (DRAM), and a Static Random Access Memory (SRAM), or may be another suitable memory. Based on that the semiconductor structure D is a memory, the storage density of the single chip package structure 10 can be increased by stacking a plurality of semiconductor structures D in the single chip package structure 10. Compared with a single semiconductor structure D, an increase in the number of the semiconductor structures D will increase the storage capacity correspondingly.

In some examples, with continued reference to FIG. 3, the semiconductor structure D includes a functional layer 12 and a dielectric layer 11 that are stacked.

The functional layer 12 may include an array layer and a peripheral device layer. The peripheral device layer is electrically connected to the array layer. The array layer includes a core area and a connection area. A plurality of memory transistor strings are disposed in the core area, and are used to store data. The core area may adjoin the connection area. The peripheral device layer is configured to receive signals, for example, including an address signal ADDR, a command signal CMD, a control signal CTRL, and a data signal DA, from outside of the semiconductor structure D, and input signals to the array layer and/or receive signals from the array layer in response to these signals, such that the semiconductor structure D may perform storage operations, for example, read, program and erase operations.

When the semiconductor structure D is a NAND cell, the functional layer 12 of the semiconductor structure D includes a NAND array layer and a NAND peripheral device layer that are stacked. When the semiconductor structure D is a DRAM cell, the functional layer 12 of the semiconductor structure D includes a DRAM array layer and a DRAM peripheral device layer that are stacked.

In some examples, with continued reference to FIG. 3, the chip package structure 10 further includes a substrate 9 on a side of the stack structure 1.

The substrate 9 is configured to provide electrical support for the stack structure 1. The substrate 9 includes a plurality of dielectric layers and a plurality of metal layers.

The metal layer is configured to provide an electrical signal to the connected stack structure 1, and is formed with fine connection lines. The material of the connection lines includes a conductive material. The conductive material may include at least one of gold (Au), silver (Ag), aluminum (Al), copper (Cu), zinc (Zn), tin (Sn), lead (Pb), antimony (Sb), bismuth (Bi), lithium (Li), gallium (Ga), and cadmium (Cd), and the like, or an alloy that contains more than two metal elements. An insulating material is located between the connection lines of the metal layer. The connection lines of different metal layers may be connected through vias.

The dielectric layer is disposed between the adjacent metal layers. The material of the dielectric layer includes an insulating material. The insulating material may include at least one of polysilicon (Si), silicon oxide, glass, polymethyl methacrylate (PMMA), polyethylene terephthalate (PET), polyethylene naphthalate two formic acid glycol ester (PEN), and ultrathin glass or polyimide (PI), etc.

In some examples, with continued reference to FIG. 3, a third conductive pillar 6 is disposed in each of the semiconductor structures D in the stack structure 1.

Along a stacking direction (e.g., a second direction Y), two adjacent semiconductor structures D in the stack structure 1 are connected through a micro-bump 8. In an example, the micro-bump 8 connects two adjacent third conductive pillars 6 in different semiconductor structures D.

During the formation of the above-mentioned stack structure 1, a through silicon via (TSV) is formed first in each semiconductor structure D configured to form the stack structure 1, the third conductive pillar 6 is formed within the through silicon via, then the micro-bump 8 corresponding to the third conductive pillar 6 is formed, and finally the plurality of semiconductor structures D are positioned and bonded. Each micro-bump 8 and third conductive pillar 6 are utilized to implement electrical connection between an upper-layer semiconductor structure D and a lower-layer semiconductor structure D (for example, the semiconductor structure D1 and the semiconductor structure D2, or the semiconductor structure D2 and the semiconductor structure D3), to form the stack structure 1.

Before the above-mentioned stack structure 1 is formed, a through silicon via (TSV) is formed in each semiconductor structure D configured to form the stack structure 1, and the third conductive pillar 6 is formed separately in each through silicon via, which results in low efficiency, complex operations, and thus high production costs. Second, in the process of positioning and bonding the plurality of semiconductor structures D, positioning error is prone to occur, which may cause connection misalignments of the plurality of semiconductor structures D, resulting in a reduced yield of the chip package structure 10.

In some examples, as shown in FIG. 4, FIG. 4 is a structural diagram of the chip package structure 10 provided by some examples. The stack structure 1 includes a first surface la and a second surface 1b that are opposite in the stacking direction (e.g., the second direction Y).

The chip package structure 10 further includes at least one first conductive pillar 31. The first conductive pillar 31 extends along the stacking direction (e.g., the second direction Y) from the first surface la of the stack structure 1, penetrates through at least one of the semiconductor structures D, and is connected to one of the semiconductor structures D.

In some examples, with continued reference to FIG. 4, the first conductive pillar 31 may extend along the stacking direction (e.g., the second direction Y) from the first surface la of the stack structure 1, penetrate through the semiconductor structure D1, and be connected to the semiconductor structure D2.

The first conductive pillar 31 may also extend along the stacking direction (the second direction Y) from the first surface 1a of the stack structure 1, sequentially penetrate through the semiconductor structure D1 and the semiconductor structure D2, and be connected to the semiconductor structure D3.

The first conductive pillar 31 may also extend along the stacking direction (the second direction Y) from the first surface la of the stack structure 1, sequentially penetrate through the semiconductor structure D1, the semiconductor structure D2, and the semiconductor structure D3, and be connected to the semiconductor structure D4.

The first conductive pillar 31 extends along the stacking direction (the second direction Y) from the first surface 1a of the stack structure 1, penetrates through at least one of the semiconductor structures D, and is connected to one of the semiconductor structures D. In an aspect, after the above-mentioned stack structure 1 is formed, a via penetrating through at least one of the semiconductor structures D may be formed within the stack structure 1, and the first conductive pillar 31 is formed within the via. The via and the first conductive pillar 31 may be both formed by a one-time process, such that operations can be simplified, which helps to improve production efficiency. In addition, the first conductive pillar 31 is formed after the formation of the stack structure 1, such that connection misalignments can be avoided during bonding of the plurality of semiconductor structures D, which helps to increase the yield of the chip package structure 10.

In another aspect, because the first conductive pillar 31 penetrates through at least one of the semiconductor structures D and is connected to one of the semiconductor structures D, e.g., one conductive pillar 31 is connected to one semiconductor structure D in the stack structure 1, but is not connected to other semiconductor structures D in the stack structure 1, the semiconductor structure D connected to the first conductive pillar 31 can be separately controlled through the first conductive pillar 31.

In some examples, the first conductive pillar 31 is an integral structure.

In some examples, the above-mentioned “the first conductive pillar 31 is an integral structure” means that the first conductive pillar 31 is integrally (or continuously) formed using the same material through the same process.

In some examples, the first conductive pillar 31 is integrally (or continuously) formed using the same material through the same process. Therefore, along the stacking direction (the second direction Y), there is no seam at a sidewall of the first conductive pillar 31, e.g., the sidewall of the first conductive pillar 31 is an even surface or a smooth surface.

In some examples, with continued reference to FIG. 4, when a plurality of first conductive pillars 31 are provided, the plurality of first conductive pillars 31 are parallel to each other, and are all parallel to the second direction Y.

In some examples, with continued reference to FIG. 4, the chip package structure 10 further includes at least one second conductive pillar 32. One end of the second conductive pillar 32 is connected to one of the semiconductor structures D closest to the first surface la of the stack structure 1 (e.g., the semiconductor structure D1), and the other end extends to the first surface 1a of the stack structure 1. That is, the second conductive pillar 32 does not penetrate through the semiconductor structure D.

In some examples, in the stack structure 1, one of the semiconductor structures D closest to the first surface 1a (e.g., the semiconductor structure D1) may be connected to the second conductive pillar 32. The semiconductor structures D (e.g., the semiconductor structure D2, the semiconductor structure D3, and the semiconductor structure D4) except the one closest to the first surface la each may be connected to at least one first conductive pillar 31.

In some examples, with continued reference to FIG. 4, the second conductive pillar 32 and the first conductive pillar 31 are parallel to each other, and are both parallel to the second direction Y.

In some examples, with continued reference to FIG. 4, the semiconductor structure D further includes a routing layer 14 located in the dielectric layer 11. The routing layer 14 is electrically connected to the functional layer 12, and is used to transmit a signal to the functional layer 12 or control the switching on/off of the functional layer 12 according to the actual requirement.

The above-mentioned “the first conductive pillar 31 extends along the stacking direction (the second direction Y) from the first surface la of the stack structure 1, penetrates through at least one of the semiconductor structures D, and is connected to one of the semiconductor structures D (e.g., the semiconductor structure D2, the semiconductor structure D3, or the semiconductor structure D4)” specifically means that the first conductive pillar 31 extends along the stacking direction (the second direction Y) from the first surface la of the stack structure 1, penetrates through at least one of the semiconductor structures D, and is connected to the routing layer 14 of one of the semiconductor structures D.

The above-mentioned “one end of the second conductive pillar 32 is connected to one of the semiconductor structures D closest to the first surface la of the stack structure 1 (e.g., the semiconductor structure D1)” specifically means that one end of the second conductive pillar 32 is connected to the routing layer 14 of one of the semiconductor structures D closest to the first surface la of the stack structure 1 (e.g., the semiconductor structure D1).

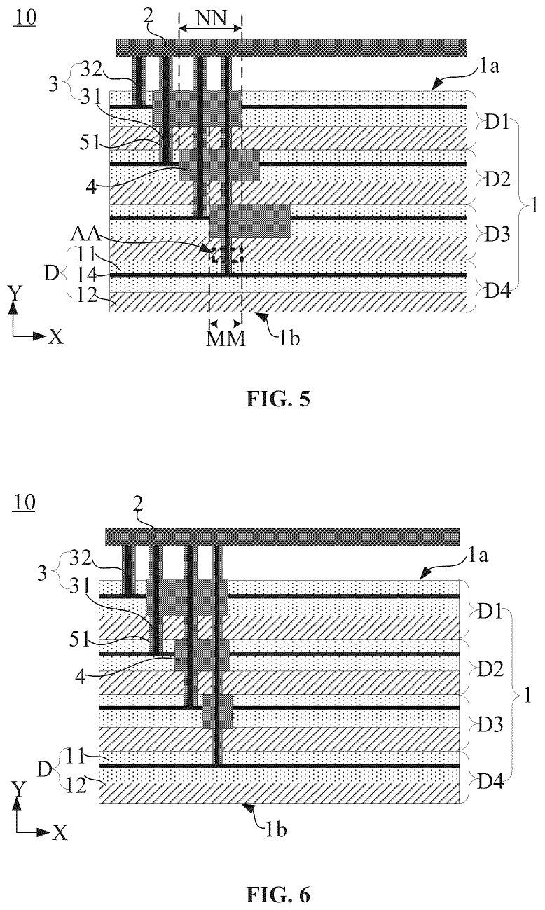

In some examples, as shown in FIGS. 4 and 5, FIG. 5 is a structural diagram of the chip package structure 10 provided by some examples. At least one semiconductor structure D further includes a dielectric block 4. The dielectric block 4 at least penetrates along the stacking direction (the second direction Y) through the routing layer 14 of the semiconductor structure D in which the dielectric block is located. The first conductive pillar 31 penetrates through the dielectric block 4 and is connected to the routing layer 14 of one semiconductor structure D located on a side of the dielectric block 4 close to the second surface 1b of the stack structure 1.

The dielectric block 4 may be used to implement insulation between the first conductive pillar 31 and the routing layer 14 of the semiconductor structure D in which the dielectric block 4 that the first conductive pillar 31 penetrates through is located.

In an example, as shown in FIG. 4, the dielectric block 4 may penetrate along the stacking direction (the second direction Y) through the routing layer 14 of the semiconductor structure D in which the dielectric block is located. For example, when the material used for forming the dielectric block 4 is the same as the material used for forming the dielectric layer 11, there is no clear physical boundary between the dielectric block 4 and the dielectric layer 11, which demonstrates that the dielectric block 4 and the dielectric layer 11 are an integral structure. The dielectric block 4 only penetrates through the routing layer 14.

In some examples, as shown in FIG. 5, the dielectric block 4 may penetrate along the stacking direction (the second direction Y) through the routing layer 14 and the dielectric layer 11 of the semiconductor structure D in which the dielectric block is located. For example, when the material used for forming the dielectric block 4 is different from the material used for forming the dielectric layer 11, there is a clear physical boundary between the dielectric block 4 and the dielectric layer 11, which demonstrates that the dielectric block 4 not only penetrates through the routing layer 14 but also penetrates through the dielectric layer 11.

In some examples, the material used for forming the dielectric block 4 may include silicon oxide.

In some examples, the dielectric block 4 may be disposed in one semiconductor structure D within the stack structure 1.

In some other examples, the dielectric block 4 may be disposed in each of the plurality of semiconductor structures D within the stack structure 1.

In some examples, as shown in FIGS. 4 and 5, the semiconductor structures (e.g., the semiconductor structure D1, the semiconductor structure D2, and the semiconductor structure D3) except the one closest to the second surface 1b of the stack structure 1 (e.g., the semiconductor structure D4) each include the dielectric block 4.

In the stacking direction (e.g., the second direction Y), a plurality of dielectric blocks 4 in different semiconductor structures D overlap in the same region (for example, an overlap region MM and an overlap region NN), and at least one first conductive pillar 31 penetrates through the plurality of dielectric blocks 4 that overlap in the same region (for example, the overlap region MM and the overlap region NN) and is connected to the routing layer 14 of one semiconductor structure D.

In some examples, as shown in FIGS. 4 and 5, the dielectric block 4 in the semiconductor structure D1, the dielectric block 4 in the semiconductor structure D2, and the dielectric block 4 in the semiconductor structure D3 have the overlap region MM. The first conductive pillar 31 may sequentially penetrate through the overlap region MM of the dielectric blocks 4 in the semiconductor structure D1, the semiconductor structure D2, and the semiconductor structure D3 and is connected to the routing layer 14 of the semiconductor structure D4.

In some examples, the dielectric block 4 in the semiconductor structure D1 and the dielectric block 4 in the semiconductor structure D2 have the overlap region NN, and the first conductive pillar 31 may sequentially penetrate through the overlap region NN of the dielectric blocks 4 in the semiconductor structure D1 and the semiconductor structure D2 and is connected to the routing layer 14 of the semiconductor structure D3.

In some examples, with continued reference to FIGS. 4 and 5, a plurality of first conductive pillars 31 are disposed as penetrating through the dielectric block 4 of at least one of the semiconductor structures D.

A plurality of first conductive pillars 31 are disposed as penetrating through one dielectric block 4, such that one dielectric block 4 may implement insulation between the plurality of first conductive pillars 31 and the routing layer 14 that the dielectric block 4 penetrates through, and it is not necessary to separately form one dielectric block 4 corresponding to each first conductive pillar 31. Thus, fabrication operations of the chip package structure 10 can be simplified, which helps to improve production efficiency.

In some examples, a plurality of first conductive pillars 31 are disposed as penetrating through the dielectric block 4 of one of the semiconductor structures D in the stack structure 1, and one first conductive pillar 31 is disposed within the dielectric block 4 of each of the other semiconductor structures D.

In some examples, the plurality of first conductive pillars 31 are disposed as penetrating through the dielectric blocks 4 of the plurality of semiconductor structures D in the stack structure 1. For example, as shown in FIGS. 4 and 5, three first conductive pillars 31 are disposed within the dielectric block 4 of the semiconductor structure D1, and two first conductive pillars 31 are disposed within the dielectric block 4 of the semiconductor structure D2.

In some examples, with continued reference to FIGS. 4 and 5, the number of the first conductive pillars 31 disposed as penetrating through the dielectric blocks 4 of the plurality of semiconductor structures D decreases sequentially along a direction from the first surface 1a of the stack structure 1 to the second surface 1b.

In some examples, three first conductive pillars 31 are disposed within the dielectric block 4 of the semiconductor structure D1, two first conductive pillars 31 are disposed within the dielectric block 4 of the semiconductor structure D2, and one first conductive pillar 31 is disposed within the dielectric block 4 of the semiconductor structure D3.

In some examples, with continued reference to FIG. 5, areas of the plurality of dielectric blocks 4 located in the different semiconductor structures D may be the same.

In some examples, the above-mentioned “the area of the dielectric block 4” refers to an area of orthographic projection of the dielectric block 4 on the first surface la of the stack structure 1 or a plane parallel to the first surface 1a. This description also applies in the descriptions regarding to “the area of the dielectric block 4” below.

When the areas of the plurality of dielectric blocks 4 in the different semiconductor structures D are the same, the plurality of dielectric blocks 4 in the different semiconductor structures D may be formed using the same process parameters, such that operations can be simplified, which helps to improve the fabrication efficiency of the chip package structure 10.

In an example, along the stacking direction (e.g., the second direction Y), the plurality of dielectric blocks 4 may be staggered along a same direction (e.g., a first direction X) parallel to the second surface 1b of the stack structure 1. That is, along the stacking direction (e.g., the second direction Y), the dielectric blocks 4 in two adjacent semiconductor structures D partially overlap.

For example, as shown in FIG. 5, along the stacking direction (e.g., the second direction Y), the dielectric block 4 in the semiconductor structure D1 and the dielectric block 4 in the semiconductor structure D2 partially overlap and have the overlap region NN. The dielectric block 4 in the semiconductor structure D1, the dielectric block 4 in the semiconductor structure D2, and the dielectric block 4 in the semiconductor structure D3 partially overlap and have the overlap region MM. An area of the overlap region MM is less than an area of the overlap region NN.

In some other examples, as shown in FIG. 6, FIG. 6 is a structural diagram of the chip package structure 10 provided by some examples. The areas of the plurality of dielectric blocks 4 located in the different semiconductor structures D decrease sequentially along the direction from the first surface la of the stack structure 1 to the second surface 1b.

In some examples, based on that the chip package structure 10 includes the plurality of first conductive pillars 31, the number of the first conductive pillars 31 disposed as penetrating through the different semiconductor structures D decreases sequentially along the direction from the first surface 1a of the stack structure 1 to the second surface 1b, e.g., the number of the first conductive pillars 31 disposed as penetrating through the dielectric blocks 4 of the different semiconductor structures D decreases sequentially. Therefore, by sequentially decreasing the areas of the plurality of dielectric blocks 4 located in the different semiconductor structures D along the direction from the first surface la of the stack structure 1 to the second surface 1b, material used for forming the dielectric blocks 4 can be saved, which helps to reduce the fabrication cost of the chip package structure 10.

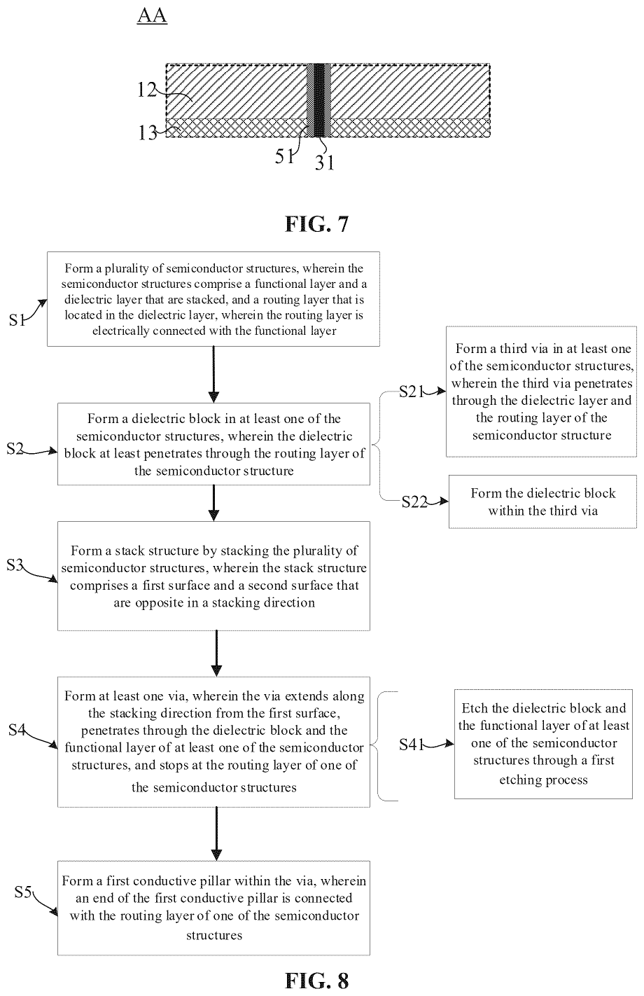

In some examples, as shown in FIG. 7, FIG. 7 is an enlarged view of a region AA of the chip package structure 10 shown in FIG. 5. The chip package structure 10 further includes at least one bonding layer 13, and two adjacent semiconductor structures D within the stack structure 1 are connected by the bonding layer 13.

In some examples, material of the bonding layer 13 may include an insulating material that can have an adhesive effect. For example, the material of the bonding layer 13 may include one or a plurality of combinations of a polyurethane, polystyrene, polyacrylate, ethylene-vinyl acetate copolymer, epoxy resin, a Die Attach Film (DAF), etc., or may include other suitable materials. The material of the bonding layer 13 includes an insulating material, and can prevent signal from transmitting between two adjacent semiconductor structures D through the bonding layer 13, thus avoiding disorder in signal transmission.

The bonding layer 13 may be also formed when two adjacent semiconductor structures D within the stack structure 1 are connected to each other through hybrid bonding. In the case that two adjacent semiconductor structures D within the stack structure 1 are connected through hybrid bonding, the plurality of semiconductor structures D may be formed on different substrates respectively, adjacent semiconductor structures D are attached together in a room temperature environment, and the temperature is then increased and annealing is performed on the adjacent semiconductor structures D. Bonding contacts disposed on opposite sides of the adjacent semiconductor structures D expand, are firmly bonded together, and thus connected together, to form the stack structure 1 in which the semiconductor structures D are bonded through hybrid bonding. A direct, short-distance (e.g., micrometer-level) electrical connection is formed between the adjacent semiconductor structures D. Compared with lead connections, an interface delay between the adjacent semiconductor structures D is eliminated, and a high-speed I/O throughput is achieved with reduced power consumption.

In some examples, with continued reference to FIGS. 5 and 7, based on that two adjacent semiconductor structures D within the stack structure 1 are connected by the bonding layer 13, the first conductive pillar 31 extends along the stacking direction (the second direction Y) from the first surface la of the stack structure 1, penetrates through at least one of the semiconductor structures D, and is connected to one of the semiconductor structures D, e.g., the first conductive pillar 31 may be connected to other semiconductor structure D than the semiconductor structure D1. Therefore, the first conductive pillar 31 at least penetrates through the bonding layer 13 between the semiconductor structure D1 and the semiconductor structure D2, the first conductive pillar 31 penetrates through at least one bonding layer 13.

In some examples, as shown in FIGS. 5 and 7, the first conductive pillar 31 may extend along the stacking direction (the second direction Y) from the first surface la of the stack structure 1, sequentially penetrate through the semiconductor structure D1 and the bonding layer 13 between the semiconductor structure D1 and the semiconductor structure D2, and be connected to the semiconductor structure D2.

The first conductive pillar 31 may also extend along the stacking direction (the second direction Y) from the first surface 1a of the stack structure 1, sequentially penetrate through the semiconductor structure D1, the bonding layer 13 between the semiconductor structure D1 and the semiconductor structure D2, the semiconductor structure D2, and the bonding layer 13 between the semiconductor structure D2 and the semiconductor structure D3, and be connected to the semiconductor structure D3.

The first conductive pillar 31 may also extend along the stacking direction (the second direction Y) from the first surface 1a of the stack structure 1, sequentially penetrate through the semiconductor structure D1, the bonding layer 13 between the semiconductor structure D1 and the semiconductor structure D2, the semiconductor structure D2, the bonding layer 13 between the semiconductor structure D2 and the semiconductor structure D3, the semiconductor structure D3, and the bonding layer 13 between the semiconductor structure D3 and the semiconductor structure D4, and be connected to the semiconductor structure D4.

In some examples, with continued reference to FIG. 7, the chip package structure further includes an insulation layer 51 surrounding the first conductive pillar 31, and located at least between the first conductive pillar 31 and the bonding layer 13 that the first conductive pillar 31 penetrates through.

In some examples, the insulation layer 51 may be located between the first conductive pillar 31 and the bonding layer 13 that the first conductive pillar 31 penetrates through.

In some examples, as shown in FIG. 7, the insulation layer 51 may also be located between the first conductive pillar 31 and the bonding layer 13 that the first conductive pillar 31 penetrates through, and between the first conductive pillar 31 and the functional layer 12 of the semiconductor structure D that the first conductive pillar 31 penetrates through. In this way, the first conductive pillar 31 and the functional layer 12 of the semiconductor structure D that the first conductive pillar 31 penetrates through can be insulated with each other.

In some examples, as shown in FIGS. 5 and 7, in the case that the first conductive pillar 31 penetrates through the semiconductor structure D1 and is connected to the semiconductor structure D2, the insulation layer 51 may be located between the first conductive pillar 31 and the bonding layer 13 between the semiconductor structure D1 and the semiconductor structure D2, and be located between the first conductive pillar 31 and the functional layer 12 of the semiconductor structure D1.

In the case that the first conductive pillar 31 sequentially penetrates through the semiconductor structure D1 and the semiconductor structure D2 and is connected to the semiconductor structure D3, the insulation layer 51 may be located between the first conductive pillar 31 and the bonding layer 13 between the semiconductor structure D1 and the semiconductor structure D2, be located between the first conductive pillar 31 and the bonding layer 13 between the semiconductor structure D2 and the semiconductor structure D3, and be located between the first conductive pillar 31 and the functional layers 12 of the semiconductor structure D1 and the semiconductor structure D2.

In the case that the first conductive pillar 31 sequentially penetrates through the semiconductor structure D1, the semiconductor structure D2, and the semiconductor structure D3 and is connected to the semiconductor structure D4, the insulation layer 51 may be located between the first conductive pillar 31 and the bonding layer 13 between the semiconductor structure D1 and the semiconductor structure D2, be located between the first conductive pillar 31 and the bonding layer 13 between the semiconductor structure D2 and the semiconductor structure D3, be located between the first conductive pillar 31 and the bonding layer 13 between the semiconductor structure D3 and the semiconductor structure D4, and be located between the first conductive pillar 31 and the functional layer 12 of the semiconductor structure D1, the semiconductor structure D2, and the semiconductor structure D3.

In some examples, material used for forming the insulation layer 51 may include at least one of polysilicon (Si), silicon oxide, glass, polymethyl methacrylate (PMMA), polyethylene terephthalate (PET), polyethylene naphthalate two formic acid glycol ester (PEN), and ultrathin glass or polyimide (PI), etc.

In some examples, with continued reference to FIGS. 4, 5 and 6, the chip package structure 10 further includes a transfer layer 2 disposed on a side of the first surface 1a of the stack structure 1. The first conductive pillar 31 and the second conductive pillar 32 each are connected to the transfer layer 2.

In some examples, the transfer layer 2 may be a redistribution layer (RDL) fabricated through a redistribution process. The redistribution layer may include a plurality of layers of metal wirings and a plurality of dielectric layers. Every two adjacent layers of metal wirings are spaced apart by the dielectric layer. The dielectric layer may be made of a resin material or other insulating materials. In order to implement electrical connection between metal wirings on different layers, a conductive channel may be fabricated in the dielectric layer, such that the metal wirings of the different layers are electrically connected through the conductive channel.

The transfer layer 2 may also be an interposer, comprising a substrate, a redistribution layer integrated on the substrate, and a conductive channel penetrating through the substrate. The conductive channel is electrically connected to a metal wiring in the redistribution layer. For example, when the substrate is a silicon substrate formed by a semiconductor material with silicon element, the interposer is a silicon interposer (Si Interposer). The routing on the silicon interposer can achieve micrometer and submicrometer-level line widths and line spacings, to meet the requirement of high-density interconnections between the plurality of semiconductor structures D.

The transfer layer 2 may further be an oxide-metal-oxide-metal (OMOM) layer. The metal may be a metal element, e.g., Ti, or a conductive metal salt, particularly a conductive metal nitride, e.g., TiN. The oxide may be silicon oxide, e.g., silicon dioxide (SiO₂). A via is disposed in the OMOM layer, and a conductive material is deposited in the via to form a conductive portion, such that each semiconductor structure D is connected to the metal layer through the conductive portion.

In an example, with continued reference to FIGS. 4, 5 and 6, a plane where the semiconductor structure D is located is approximately parallel to a plane where the transfer layer 2 is located. For example, an included angle between the plane where the semiconductor structure D is located and the plane where the transfer layer 2 is located may be less than or equal to 5 degrees.

A fabrication method of the above-mentioned chip package structure 10 is described below in detail.

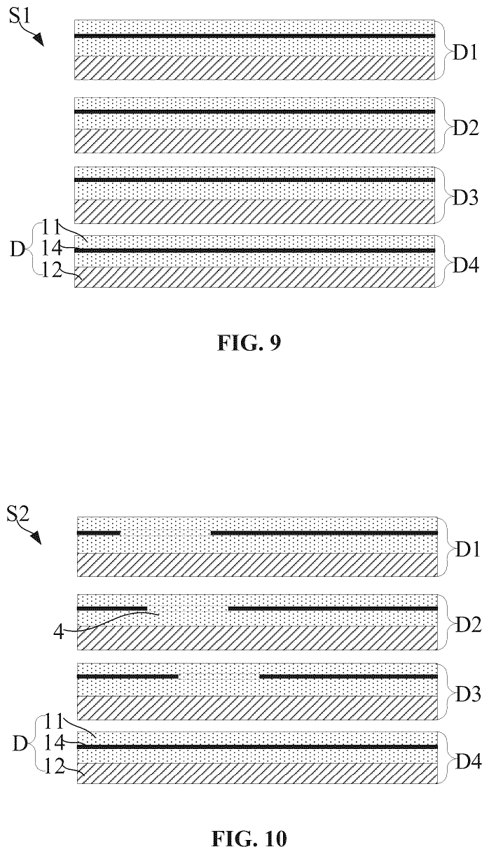

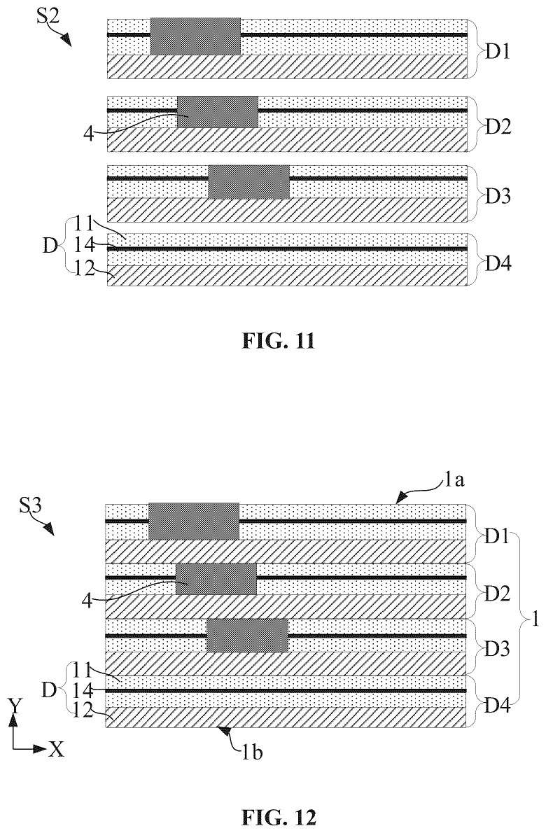

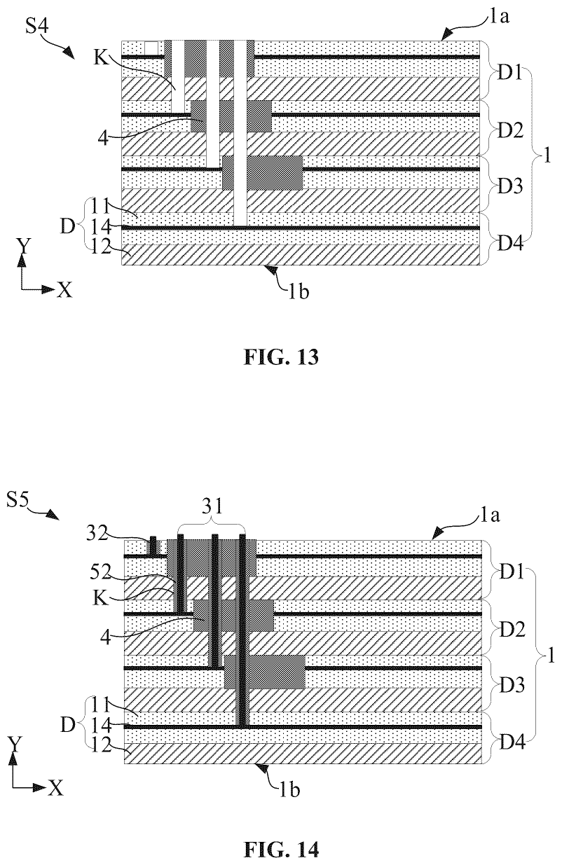

In some examples, as shown in FIGS. 8-14, FIG. 8 is a flow diagram of a fabrication method of a chip package structure 10 provided by some examples. FIG. 9 is a structural diagram corresponding to operation S1 in the fabrication method of the chip package structure 10 shown in FIG. 8. FIGS. 10 and 11 are structural diagrams corresponding to operation S2 in the fabrication method of the chip package structure 10 shown in FIG. 8. FIG. 12 is a structural diagram corresponding to operation S3 in the fabrication method of the chip package structure 10 shown in FIG. 8. FIG. 13 is a structural diagram corresponding to operation S4 in the fabrication method of the chip package structure 10 shown in FIG. 8. FIG. 14 is a structural diagram corresponding to operation S5 in the fabrication method of the chip package structure 10 shown in FIG. 8. The fabrication method of the chip package structure 10 includes the following operations:
S1: as shown in FIG. 9, forming a plurality of semiconductor structures D, wherein the semiconductor structures D include a functional layer 12 and a dielectric layer 11 that are stacked, and a routing layer 14 that is located in the dielectric layer 11, wherein the routing layer 14 is electrically connected to the functional layer 12;
S2: as shown in FIG. 10 or 11, forming a dielectric block 4 in at least one of the semiconductor structures D, wherein the dielectric block 4 at least penetrates through the routing layer 14 of the semiconductor structure D;
S3: as shown in FIG. 12, forming a stack structure 1 by stacking the plurality of semiconductor structures D, wherein the stack structure 1 includes a first surface la and a second surface 1b that are opposite in a stacking direction (a second direction Y).
S4: as shown in FIG. 13, forming at least one via K, wherein the via K extends along the stacking direction (the second direction Y) from the first surface la of the stack structure 1, penetrates through the dielectric block 4 and the functional layer 12 of at least one of the semiconductor structures D, and stops at the routing layer 14 of one of the semiconductor structures D; and
S5: as shown in FIG. 14, forming a first conductive pillar 31 within the via K, wherein an end of the first conductive pillar 31 is connected to the routing layer 14 of one of the semiconductor structures D.

In some examples, the structural diagram corresponding to the operation S3 in the fabrication method of the chip package structure 10 shown in FIG. 12 is based on the structural diagram corresponding to the operation S2 in the fabrication method of the chip package structure 10 shown in FIG. 11 (e.g., the dielectric block 4 in the semiconductor structure D not only penetrates through the routing layer 14 but also penetrates through the dielectric layer 11), and is an illustrative description of the operation S3 in the fabrication method of the chip package structure 10. Based on the structural diagram corresponding to the operation S2 in the fabrication method of the chip package structure 10 shown in FIG. 10 (e.g., the dielectric block 4 in the semiconductor structure D only penetrates through the routing layer 14), FIGS. 12-14 may be referred to when performing the operations S3-S5 in the fabrication method of the chip package structure 10.

After the stack structure 1 is formed, the via K penetrating through the dielectric block 4 and the functional layer 12 of at least one of the semiconductor structures D is formed within the stack structure 1, and the first conductive pillar 31 is formed within the via K, such that connection misalignments during the bonding of the plurality of semiconductor structures D can be avoided, which helps to increase a yield of the chip package structure 10.

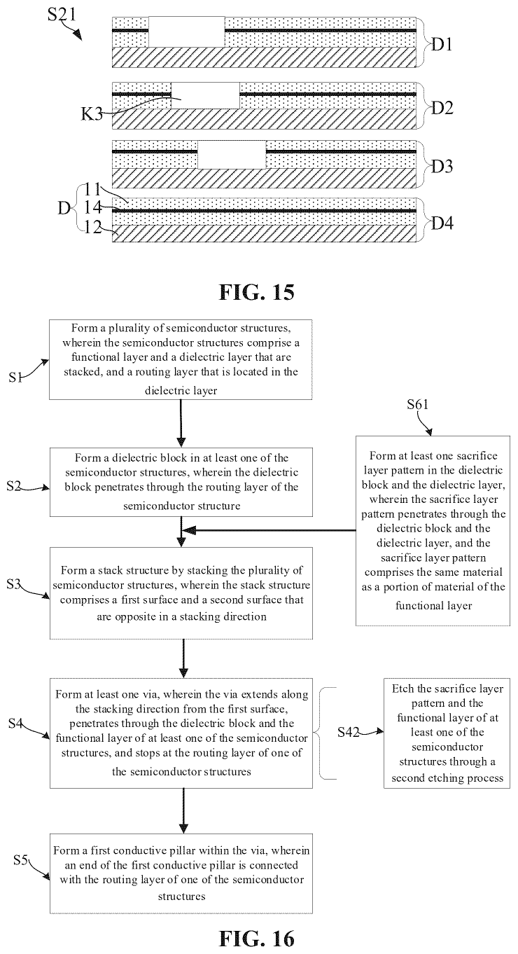

In some examples, with continued reference to FIG. 8, and in combination with FIGS. 10, 11 and 15, FIG. 15 is a structural diagram corresponding to operation S21 in the fabrication method of the chip package structure 10 shown in FIG. 8. The operation S2 in the fabrication method of the chip package structure 10 may include the operation S21 and operation S22:
S21: as shown in FIG. 15, forming a third via K3 in at least one of the semiconductor structures D, wherein the third via K3 penetrates through the dielectric layer 11 and the routing layer 14 of the semiconductor structure D; and
S22: as shown in FIG. 10 and FIG. 11, forming the dielectric block 4 within the third via K3.

In some examples, as shown in FIG. 10, the material used for forming the dielectric block 4 may be the same as the material used for forming the dielectric layer 11. For example, the material used for forming the dielectric block 4 and the material used for forming the dielectric layer 11 both include silicon oxide.

In some examples, when the material used for forming the dielectric block 4 is the same as the material used for forming the dielectric layer 11, there is no clear physical boundary between the dielectric block 4 and the dielectric layer 11, which demonstrates that along the stacking direction (the second direction Y), the dielectric block 4 only penetrates through the routing layer 14.

In some examples, as shown in FIG. 11, the material used for forming the dielectric block 4 may be different from the material used for forming the dielectric layer 11.

In some examples, when the material used for forming the dielectric block 4 is different from the material used for forming the dielectric layer 11, there is a clear physical boundary between the dielectric block 4 and the dielectric layer 11, which demonstrates that the dielectric block 4 not only penetrates through the routing layer 14 but also penetrates through the dielectric layer 11.

In an example, the third via K3 may be formed in one of the semiconductor structures D; In some examples, as shown in FIG. 15, the third via K3 may be formed in each of the plurality of semiconductor structures D. For example, the third via K3 is formed in each of a semiconductor structure D1, a semiconductor structure D2, and a semiconductor structure D3.

When the third via K3 is formed in one of the semiconductor structures D, the dielectric block 4 formed within the third via K3 is also disposed in one of the semiconductor structures D. When the third via K3 is formed in each of the plurality of semiconductor structures D, the dielectric blocks 4 formed within the third vias K3 are also disposed in the plurality of semiconductor structures D. For example, as shown in FIGS. 10 and 11, the dielectric block 4 is formed in each of the semiconductor structure D1, the semiconductor structure D2, and the semiconductor structure D3.

In some examples, with continued reference to FIG. 8, the operation S4 in the fabrication method of the chip package structure 10 includes operation S41:
S41: etching the dielectric block 4 and the functional layer 12 of at least one of the semiconductor structures D through a first etching process.

In some examples, the first etching process includes a plasma etching process. The plasma etching process uses an etching gas (e.g., BCl₃). The semiconductor structure D is etched using Inductively Coupled Plasma (IPC) dry etching.

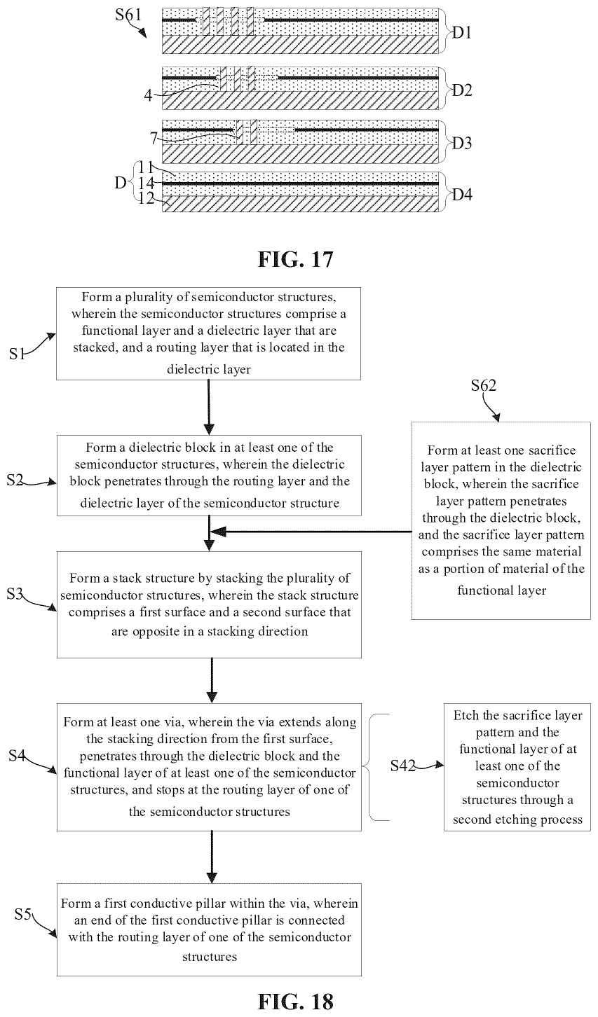

In some examples, as shown in FIGS. 16 and 17, FIG. 16 is a flow diagram of a fabrication method of a chip package structure 10 provided by some examples, and FIG. 17 is a structural diagram corresponding to operation S61 in the fabrication method of the chip package structure 10 shown in FIG. 16. Based on that the dielectric block 4 penetrates along the stacking direction (the second direction Y) through the routing layer 14 of the semiconductor structure D in which the dielectric block is located, between the operation S2 and the operation S3 in the above-mentioned fabrication method of the chip package structure 10, the fabrication method of the chip package structure 10 further includes the operation S61:
S61: as shown in FIG. 17, forming at least one sacrificial layer pattern 7 in the dielectric block 4 and the dielectric layer 11, wherein the sacrificial layer pattern 7 penetrates through the dielectric block 4 and the dielectric layer 11.

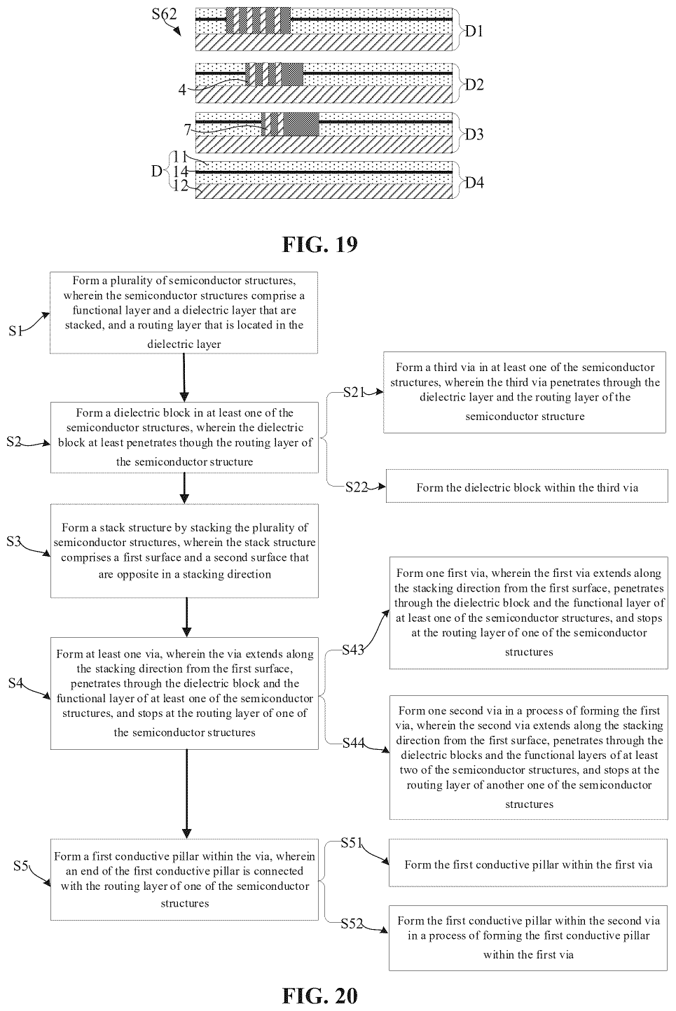

In some other examples, as shown in FIGS. 18 and 19, FIG. 18 is a flow diagram of a fabrication method of a chip package structure 10 provided by some examples, and FIG. 19 is a structural diagram corresponding to operation S62 in the fabrication method of the chip package structure 10 shown in FIG. 18. Based on that the dielectric block 4 penetrates along the stacking direction (the second direction Y) through the routing layer 14 and the dielectric layer 11 of the semiconductor structure D in which the dielectric block is located, between the operation S2 and the operation S3 in the above-mentioned fabrication method of the chip package structure 10, the fabrication method of the chip package structure 10 further includes the operation S62:
S62: as shown in FIG. 19, forming at least one sacrificial layer pattern 7 in the dielectric block 4, wherein the sacrificial layer pattern 7 penetrates through the dielectric block 4.

In an example, the sacrificial layer pattern 7 includes the same material as a portion of material of the functional layer 12. For example, the material of the sacrificial layer pattern 7 and the material of the functional layer 12 both include polysilicon.

In some examples, with continued reference to FIGS. 16 and 18, the operation S4 in the fabrication method of the chip package structure 10 includes operation S42:
S42: etching the sacrificial layer pattern 7 and the functional layer 12 of at least one of the semiconductor structures D through a second etching process.

In the case that the material of the sacrificial layer pattern 7 is the same as the material of the functional layer 12, during the etching of the sacrificial layer pattern 7 and the functional layer 12 of at least one of the semiconductor structures D to form the via K, etching only needs to be performed on the same material, which helps to reduce etching difficulty and improve etching efficiency.

In some examples, the second etching process includes a wet etching process. The wet etching process is to immerse the semiconductor structure D in a corrosive solution for etching. For example, a corrosive solution used by a wet alkaline corrosion process may include at least one of a NaOH solution and a KOH solution.

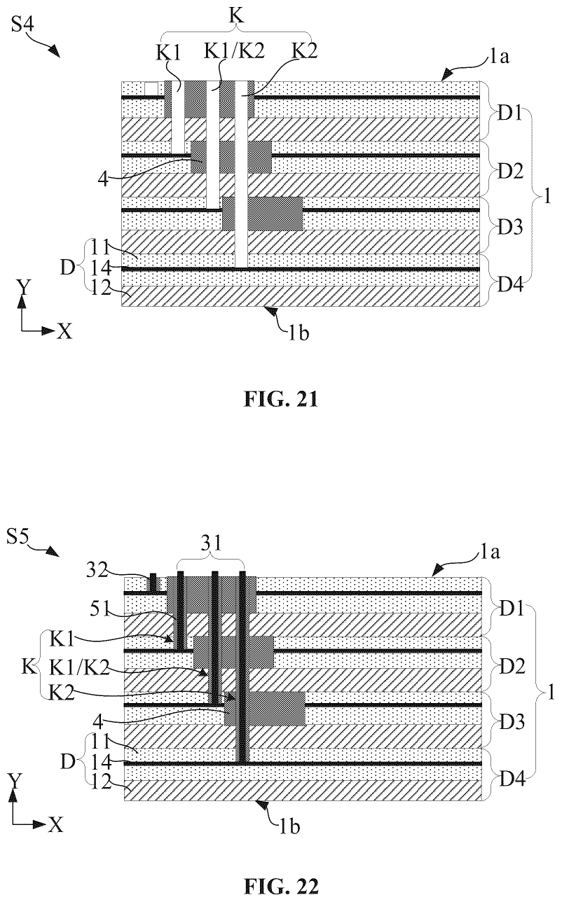

In some examples, as shown in FIGS. 20 and 21, FIG. 20 is a flow diagram of a fabrication method of a chip package structure 10 provided by some examples, and FIG. 21 is a structural diagram corresponding to operation S4 in the fabrication method of the chip package structure 10 shown in FIG. 20. The operation S4 in the fabrication method of the chip package structure 10 may include the operation S43 and operation S44:
S43: form one first via K1, wherein the first via K1 extends along the stacking direction (the second direction Y) from the first surface la of the stack structure 1, penetrates through the dielectric block 4 and the functional layer 12 of at least one of the semiconductor structures D, and stops at the routing layer 14 of one of the semiconductor structures D; and
S44: forming one second via K2 in a process of forming the first via K1, wherein the second via K2 extends along the stacking direction (the second direction Y) from the first surface la of the stack structure 1, penetrates through the dielectric blocks 4 and the functional layers 12 of at least two of the semiconductor structures D, and stops at the routing layer 14 of another one of the semiconductor structures D.

In some examples, as shown in FIG. 21, the first via K1 may extend along the stacking direction (the second direction Y) from the first surface la of the stack structure 1, penetrate through the dielectric block 4 and the functional layer 12 of the semiconductor structure D1, and stop at the routing layer 14 of the semiconductor structure D2.

In some examples, the first via K1 may also extend along the stacking direction (the second direction Y) from the first surface la of the stack structure 1, respectively penetrate through the dielectric blocks 4 and the functional layers 12 of the semiconductor structure D1 and the semiconductor structure D2, and stop at the routing layer 14 of the semiconductor structure D3.

The second via K2 may extend along the stacking direction (the second direction Y) from the first surface 1a of the stack structure 1, respectively penetrate through the dielectric blocks 4 and the functional layers 12 of the semiconductor structure D1 and the semiconductor structure D2, and stop at the routing layer 14 of the semiconductor structure D3.

The second via K2 may also extend along the stacking direction (the second direction Y) from the first surface la of the stack structure 1, respectively penetrate through the dielectric blocks 4 and the functional layers 12 of the semiconductor structure D1, the semiconductor structure D2, and the semiconductor structure D3, and stop at the routing layer 14 of the semiconductor structure D4.

In some examples, the first via K1 and the second via K2 are different vias K. Therefore, in this example, when the first via K1 may extend along the stacking direction (the second direction Y) from the first surface la of the stack structure 1, penetrate through the dielectric block 4 and the functional layer 12 of the semiconductor structure D1, and stop at the routing layer 14 of the semiconductor structure D2, the second via K2 may extend along the stacking direction (the second direction Y) from the first surface la of the stack structure 1, respectively penetrate through the dielectric blocks 4 and the functional layers 12 of the semiconductor structure D1 and the semiconductor structure D2, and stop at the routing layer 14 of the semiconductor structure D3. In some examples, the second via K2 may also extend along the stacking direction (the second direction Y) from the first surface la of the stack structure 1, respectively penetrate through the dielectric blocks 4 and the functional layers 12 of the semiconductor structure D1, the semiconductor structure D2, and the semiconductor structure D3, and stop at the routing layer 14 of the semiconductor structure D4.

When the first via K1 extends along the stacking direction (the second direction Y) from the first surface la of the stack structure 1, respectively penetrates through the dielectric blocks 4 and the functional layers 12 of the semiconductor structure D1 and the semiconductor structure D2, and stops at the routing layer 14 of the semiconductor structure D3, the second via K2 may extend along the stacking direction (the second direction Y) from the first surface la of the stack structure 1, respectively penetrate through the dielectric blocks 4 and the functional layers 12 of the semiconductor structure D1, the semiconductor structure D2, and the semiconductor structure D3, and stop at the routing layer 14 of the semiconductor structure D4.

In some examples, the first via K1 and the second via K2 may be formed synchronously in the same process, which helps to shorten the fabrication time of the chip package structure 10 and increase the fabrication efficiency of the chip package structure 10.

In some examples, as shown in FIGS. 20 and 22, FIG. 22 is a structural diagram corresponding to operation S5 in the fabrication method of the chip package structure 10 shown in FIG. 20. The operation S5 in the fabrication method of the chip package structure 10 may include the operation S52 and operation S52:
S51: forming the first conductive pillar 31 within the first via K1; and
S52: forming the first conductive pillar 31 within the second via K2 in a process of forming the first conductive pillar 31 within the first via K1.

In some examples, the first conductive pillar 31 within the first via K1 and the first conductive pillar 31 within the second via K2 may be formed synchronously in the same process, which further helps to shorten the fabrication time of the chip package structure 10 and further increase the fabrication efficiency of the chip package structure 10.

The above descriptions are merely particular implementations of the present disclosure, and the protection scope of the present disclosure is not limited to those. Any variation or replacement that may be readily figured out by those skilled in the art within the technical scope disclosed by the present disclosure shall be encompassed within the protection scope of the present disclosure. Therefore, the scope of protection of the present disclosure should be defined by the scope of protection of the claims.

What is claimed is:

1. A chip package structure, comprising:
a stack structure comprising a plurality of semiconductor structures that are stacked, wherein the stack structure comprises a first surface and a second surface that are opposite in a stacking direction; and
at least one first conductive pillar, wherein the first conductive pillar extends along the stacking direction from the first surface of the stack structure, penetrates through at least one of the semiconductor structures, and is connected to one of the semiconductor structures.

2. The chip package structure of claim 1, wherein the first conductive pillar is an integral structure; and
a sidewall of the first conductive pillar is an even surface or a smooth surface along the stacking direction.

3. The chip package structure of claim 1, wherein the semiconductor structures comprise a functional layer and a dielectric layer that are stacked, and a routing layer that is located in the dielectric layer, wherein the routing layer is electrically connected to the functional layer;
at least one of the semiconductor structures further comprises a dielectric block, and the dielectric block at least penetrates along the stacking direction through the routing layer of the semiconductor structure in which the dielectric block is located; and
the first conductive pillar penetrates through the dielectric block and is connected to the routing layer of one of the semiconductor structures located on a side of the dielectric block close to the second surface.

4. The chip package structure of claim 3, wherein the semiconductor structures except the one closest to the second surface each comprise the dielectric block; and
in the stacking direction, a plurality of dielectric blocks located in different semiconductor structures overlap in a same region, and the at least one first conductive pillar penetrates through the plurality of dielectric blocks that overlap in the same region and is connected to the routing layer of one of the semiconductor structures.

5. The chip package structure of claim 4, wherein a plurality of first conductive pillars are disposed as penetrating through the dielectric block of at least one of the semiconductor structures.

6. The chip package structure of claim 4, wherein a number of the first conductive pillars disposed as penetrating through the dielectric blocks of the plurality of semiconductor structures decreases sequentially along a direction from the first surface to the second surface.

7. The chip package structure of claim 4, wherein areas of the plurality of dielectric blocks located in the different semiconductor structures are the same.

8. The chip package structure of claim 7, wherein along the stacking direction, the plurality of dielectric blocks are staggered along a same direction parallel to the second surface.

9. The chip package structure of claim 4, wherein areas of the plurality of dielectric blocks located in the different semiconductor structures decrease sequentially along a direction from the first surface to the second surface.

10. The chip package structure of claim 3, further comprising at least one bonding layer, wherein two adjacent ones of the semiconductor structures are connected by the bonding layer; and
the first conductive pillar penetrates through the at least one bonding layer.

11. The chip package structure of claim 10, further comprising an insulation layer surrounding the first conductive pillar and located at least between the first conductive pillar and the bonding layer that the first conductive pillar penetrates through,
wherein the insulation layer is further located between the first conductive pillar and the functional layer of the semiconductor structure that the first conductive pillar penetrates through.

12. The chip package structure of claim 1, wherein the chip package structure comprises a plurality of first conductive pillars, and the semiconductor structures except the one closest to the first surface each are connected to at least one of the first conductive pillars; and
the chip package structure further comprises at least one second conductive pillar, one end of the second conductive pillar is connected to the semiconductor structure closest to the first surface, and the other end of the second conductive pillar extends to the first surface.

13. The chip package structure of claim 12, further comprising a transfer layer disposed on a side of the first surface of the stack structure; and
the first conductive pillar and the second conductive pillar each are connected to the transfer layer.

14. A fabrication method of a chip package structure, comprising:
forming a plurality of semiconductor structures, wherein the semiconductor structures comprise a functional layer and a dielectric layer that are stacked, and a routing layer that is located in the dielectric layer, wherein the routing layer is electrically connected to the functional layer;
forming a dielectric block in at least one of the semiconductor structures, wherein the dielectric block at least penetrates through the routing layer of the semiconductor structure;
forming a stack structure by stacking the plurality of semiconductor structures, wherein the stack structure comprises a first surface and a second surface that are opposite in a stacking direction;
forming a via, wherein the via extends along the stacking direction from the first surface, penetrates through the dielectric block and the functional layer of at least one of the semiconductor structures, and stops at the routing layer of one of the semiconductor structures; and
forming a first conductive pillar within the via, wherein an end of the first conductive pillar is connected to the routing layer of one of the semiconductor structures.

15. The fabrication method of the chip package structure of claim 14, wherein the forming the via comprises:
etching the dielectric block and the functional layer of at least one of the semiconductor structures through a first etching process.

16. The fabrication method of the chip package structure of claim 15, wherein the first etching process comprises a plasma etching process.

17. The fabrication method of the chip package structure of claim 14, wherein based on that the dielectric block penetrates along the stacking direction through the routing layer of the semiconductor structure in which the dielectric block is located, between the forming the dielectric block in at least one of the semiconductor structures and the forming the stack structure by stacking the plurality of semiconductor structures, the fabrication method further comprises:
forming at least one sacrificial layer pattern in the dielectric block and the dielectric layer, wherein the sacrificial layer pattern penetrates through the dielectric block and the dielectric layer, and the sacrificial layer pattern comprises a same material as a portion of material of the functional layer;
based on that the dielectric block penetrates along the stacking direction through the routing layer and the dielectric layer of the semiconductor structure in which the dielectric block is located, between the forming the dielectric block in at least one of the semiconductor structures and the forming the stack structure by stacking the plurality of semiconductor structures, the fabrication method further comprises:
forming at least one sacrificial layer pattern in the dielectric block, wherein the sacrificial layer pattern penetrates through the dielectric block, and the sacrificial layer pattern comprises a same material as a portion of material of the functional layer; and
the forming the via comprises:
etching the sacrificial layer pattern and the functional layer of at least one of the semiconductor structures through a second etching process.

18. The fabrication method of the chip package structure of claim 17, wherein the second etching process comprises a wet etching process.

19. The fabrication method of the chip package structure of claim 14, wherein the forming the via comprises:
forming a first via, wherein the first via extends along the stacking direction from the first surface, penetrates through the dielectric block and the functional layer of at least one of the semiconductor structures, and stops at the routing layer of one of the semiconductor structures; and
forming a second via in a process of forming the first via, wherein the second via extends along the stacking direction from the first surface, penetrates through the dielectric blocks and the functional layers of at least two of the semiconductor structures, and stops at the routing layer of another one of the semiconductor structures; and
the forming the first conductive pillar within the via comprises:
forming the first conductive pillar within the first via; and
forming the first conductive pillar within the second via in a process of forming the first conductive pillar within the first via.

20. A memory system, comprising:
a chip package structure, comprising:
a stack structure comprising a plurality of semiconductor structures that are stacked, wherein the stack structure comprises a first surface and a second surface that are opposite in a stacking direction; and
at least one first conductive pillar, wherein the first conductive pillar extends along the stacking direction from the first surface of the stack structure, penetrates through at least one of the semiconductor structures, and is connected to one of the semiconductor structures; and
a controller connected to the chip package structure.
